(19) United States
(12) Patent Application Publication
(10) Pub. No.: US 2009/0186443 A1
(43) Pub. Date: Jul. 23, 2009

(54) METHOD TO ENHANCE PERFORMANCE OF COMPLEX METAL OXIDE PROGRAMMABLE MEMORY

(75) Inventors: Eric A. Joseph, White Plains, NY (US); Chung Hon Lam, Peekskill, NY (US); Gerhard I. Meijer, Zurich (NL); Stephen M. Rossnagel, Pleasantville, NY (US); Alejandro Gabriel Schrott, New York, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION

(21) Appl. No.: 12/017,848

(22) Filed: Jan. 22, 2008

(51) Int. Cl. H01L 21/34

(52) U.S. Cl. 438/104; 257/E21.46

(57) ABSTRACT

A method of incorporating oxygen vacancies near an electrode/oxide interface region of a complex metal oxide programmable memory cell which includes forming a first electrode of a metallic material which remains metallic upon oxidation, forming a second electrode facing the first electrode, forming an oxide layer in between the first and second electrodes, applying an electrical signal to the first electrode such that oxygen ions from the oxide layer are embedded in and oxidize the first electrode, and forming oxygen vacancies near the electrode/oxide interface region of the complex metal oxide programmable memory cell.

### BACKGROUND OF THE INVENTION

1. Field of the Invention

This invention relates to a nonvolatile memory cell for use in integrated circuits and, more particularly, to a method of incorporating oxygen vacancies near an electrode/oxide interface region of a complex metal oxide (CMO) programmable memory cell.

2. Description of Background

In a nonvolatile memory cell, electrical resistance of resistance-switching materials including, for example, transition-metal oxides, metal sulphides, and metal selenides can be changed significantly by external influences such as electrical fields, magnetic fields, and temperature. Electrical impulses which are applied to these resistance-switching materials can “program” memory devices, such that they exhibit a desired resistive property.

The transition-metal oxides, metal sulphides, and metal selenides are classes of material that can be conditioned such that they exhibit the desired bi-stable electrical resistance. A conditioning process for these resistance-switching materials involves subjecting the insulating dielectric material to an appropriate electrical signal for a sufficient period of time. The conditioning process generates a confined conductive region of arbitrary shape in the transition-metal oxide, metal sulphide and metal selenides. The confined conductive region is formed near local perturbations such as vacancies, defects, impurities, grain boundaries or roughness, for example. The conditioning process of the programmable resistance-switching materials can be accelerated, for example, by incorporating oxygen vacancies in the transition-metal oxides during the fabrication process. Conventionally, an interface region near electrodes can be reversibly switched between two or more resistance states by applying a pulse of electrical current to the materials. However, vacancy incorporation near the electrode or near an asperity is difficult to achieve.

### SUMMARY OF THE INVENTION

The shortcomings of the prior art are overcome and additional advantages are provided through the provision of a method of incorporating oxygen vacancies near an electrode/oxide interface region of a complex metal oxide programmable memory cell, the method includes forming a first electrode of a metallic material which remains metallic upon oxidation, forming a second electrode facing the first electrode, forming an oxide layer between the first and second electrodes, applying an electrical signal to the first electrode such that oxygen ions from the oxide layer are embedded in and oxidize the first electrode, and forming oxygen vacancies near the electrode/oxide interface region of the complex metal oxide programmable memory cell.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

Embodiments of the present invention create a solution for incorporating oxygen vacancies near an electrode/oxide interface region of a complex metal oxide (CMO) programmable memory cell and in a region of the electrode/oxide interface region immediately adjacent to a bump formed on an electrode surface of the CMO programmable memory cell.

As a result of the summarized invention, technically we have achieved a solution which enables the incorporation of the oxygen vacancies such that the conditioning process is more readily initiated.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a schematic diagram illustrating an example of a nonvolatile programmable memory cell that can be implemented within embodiments of the present invention.

FIGS. 2A and 2B are schematic diagrams illustrating resistance states of the nonvolatile programmable memory cell of FIG. 1 that can be implemented within embodiments of the present invention.

FIG. 3 is a flow chart detailing aspects of a method of incorporating oxygen vacancies near an electrode/oxide interface region of the nonvolatile programmable memory cell of FIG. 1 that can be implemented within aspects of the present invention.

FIGS. 4A and 4B are schematic diagrams illustrating an example of the formation of bumps on an electrode of the nonvolatile programmable memory cell of FIG. 1 that can be implemented within embodiments of the present invention.

FIGS. 5A and 5B are schematic diagrams illustrating another example of a nonvolatile programmable memory cell with reference to FIG. 4B that can be implemented within embodiments of the present invention.

### DETAILED DESCRIPTION OF THE INVENTION

Turning now to the drawings in greater detail, it will be seen that in FIG. 1 there is a nonvolatile programmable memory cell 100 which includes a first electrode 110, a second electrode 112 and an oxide layer 114 formed between the first electrode 110 and the second electrode 112.

According to an exemplary embodiment, the first electrode 110 is formed of a metallic material which remains metallic upon oxidation thereof. According to one exemplary embodiment, the first electrode 110 is made of ruthenium (Ru). However, the present invention is not limited hereto, and may vary accordingly. That is, according to alternative exemplary embodiments of the present invention, the first electrode 110 may be made of an electrode material such as iridium (Ir) or vanadium (V).

Further, according to an exemplary embodiment, the second electrode 112 is made of platinum (Pt). However, the present invention is not limited hereto, and may vary accordingly.

According to an exemplary embodiment, the oxide layer 114 is a complex metal oxide (CMO) such as a transition-metal oxide. It may comprise materials with a perovskite structure such as, SrTiO_{3-δ}, BaTiO_{3-δ}, (Sr,Ba)TiO_{3-δ}, SrZrO_{3-δ}, and (Pr,Ca)MnO_{3-δ}. However, the present invention is not limited hereto. According to an alternative embodiment, the oxide layer 114 may be made of binary transition-metal oxides such as nickel oxide NiO_{δ} and titanium oxide TiO_{δ}.

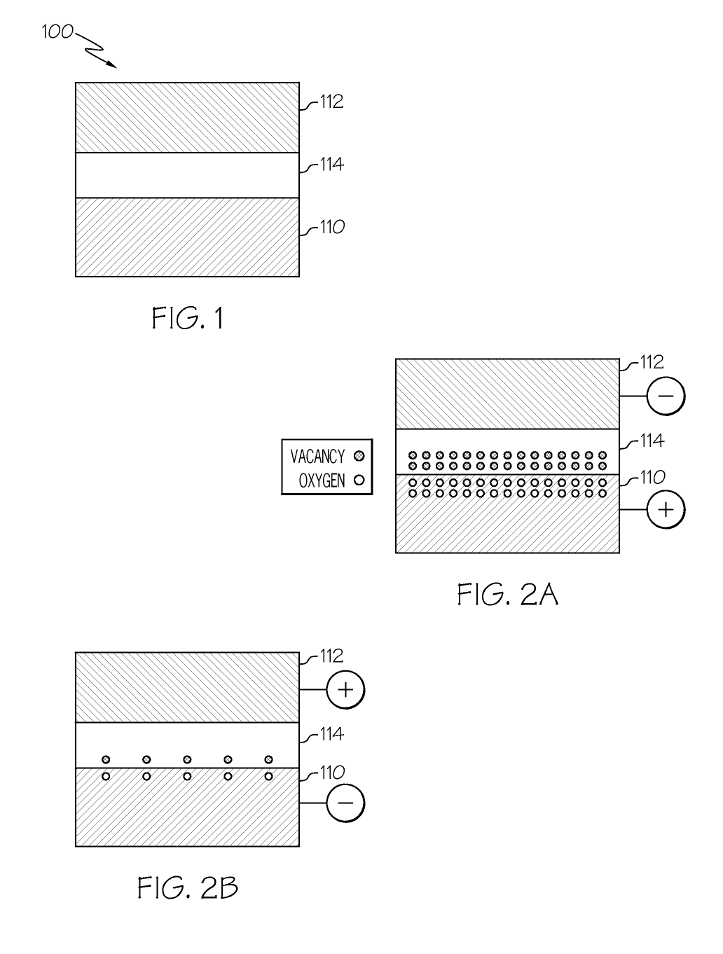

FIGS. 2A and 2B are schematic diagrams illustrating resistance states of the nonvolatile memory cell of FIG. 1 that can be implemented within embodiments of the present invention. The electrode/oxide interface region near the first electrode 110 can be reversibly switched between two or more resistance states by applying an electrical signal to the materials. Thus, FIGS. 2A and 2b illustrate two resistance states (i.e., a low resistance state and a high resistance state) associated with the migration of oxygen ions in the memory cell 100.

As shown in FIG. 2A, according to an exemplary embodiment, when in a State 1, which is a low resistance state, a positive voltage is applied to the first electrode 110 which causes the migration of oxygen ions from the oxide layer 114 towards the first electrode 110. The oxygen ions from the oxide layer 114 become embedded in and oxidize the first electrode 110 which remains conductive after oxidation. For example, according to one exemplary embodiment, when the first electrode 110 is a Ru electrode, after oxidation the Ru electrode will remain conductive due to the properties of Ru oxide (RuO₂). Alternatively, according to another exemplary embodiment, when the first electrode 110 is made of Ir or V, the first electrode 110 will remain conductive after oxidation due to properties of iridium oxide (IrO₂) and vanadium oxide (V₂O₃), respectively. The electrode/oxide interface region near the first electrode 110 is reversibly switched between a low resistance state as shown in FIG. 2A, and a high resistance state as shown in FIG. 2B, for example, associated with the migration of oxygen ions.

As further shown in FIG. 2A, when the oxygen ions from the oxide layer 114 become embedded in and oxidize the first electrode 110, oxygen vacancies are left in an oxide side of the electrode/oxide interface region. The oxide side is the side of the oxide layer 114 which faces the first electrode 110. According to an exemplary embodiment, a thickness of the oxide layer 114 forms a tunneling barrier and the formation of oxygen vacancies at the electrode/oxide interface region generates a thinner tunneling barrier and therefore a tunneling current through the oxide layer 114. According to an exemplary embodiment, the thickness of the oxide layer 114 is between approximately 0.8 nm and 10 nm, for example.

As shown in FIG. 2A, when in a low resistance state, the oxide layer 114 and first electrode 110 after oxidation, for example, the Ru oxide (RuO₂), are both in a low resistance state.

As shown in FIG. 2B, when switching from a first state to a second state i.e., from a low resistance state to a high resistance state, oxygen vacancies and oxygen ions are pulled from the oxide layer 114 and the first electrode 110 respectively. As a result, the oxide layer 114 is in a high resistance state while the first electrode 110 remains in a low resistance state. According to an exemplary embodiment, the RuO₂ is reduced to Ru in the high resistance state.

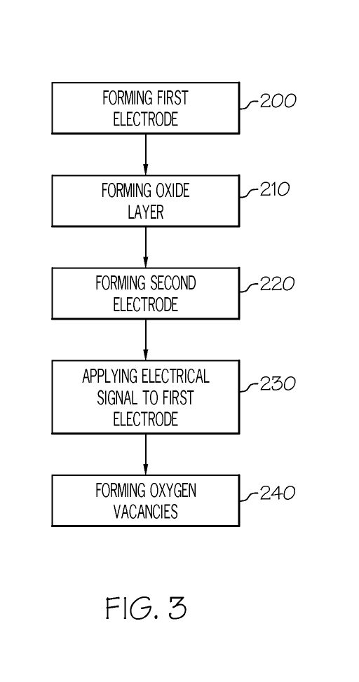

FIG. 3 is a flow chart detailing aspects of a method of incorporating oxygen vacancies near an electrode/oxide interface region of the nonvolatile programmable memory cell of FIG. 1 that can be implemented within aspects of the present invention.

Specifically, as shown in FIG. 3, the process begins at operation 200, where the first electrode 110 of a metallic material which remains metallic upon oxidation, is formed. From operation 200, the process moves to operation 210 where the oxide layer 114 is formed. From operation 210, the process moves to operation 220 where the second electrode 112 is formed on the oxide layer. From operation 220, the process moves to operation 230, where an electrical signal is applied to the first electrode 110 such that oxygen ions from the oxide layer 114 are embedded in and oxidize the first electrode 110. Upon oxidation of the first electrode 110 in operation 230, the process moves to operation 240, where oxygen vacancies are then formed near the electrode/oxide interface region of the programmable memory cell 100, the electrode/oxide interface region being a region where the first electrode 110 and the oxide layer 114 are interfaced.

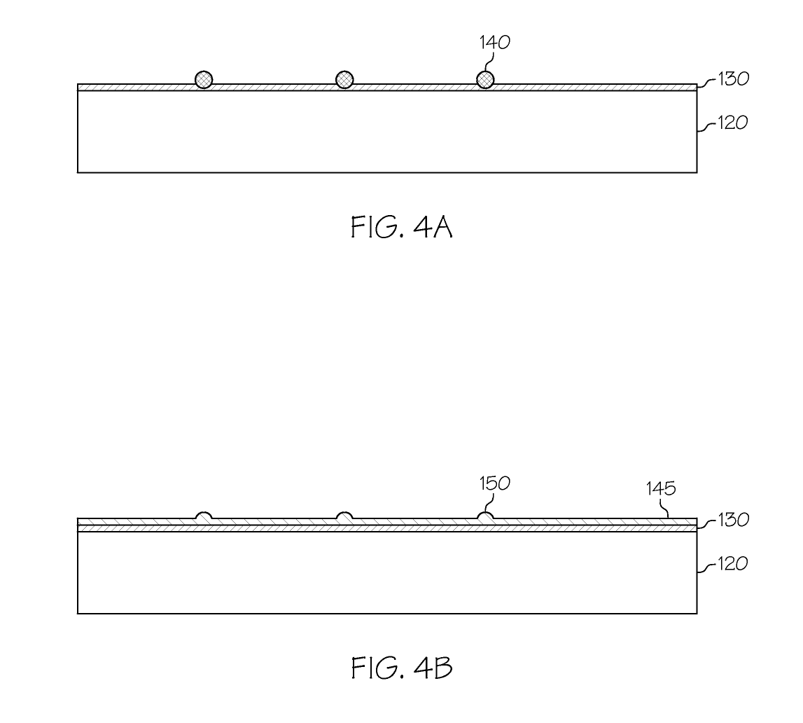

FIGS. 4A and 4B are schematic diagrams illustrating an example of the formation of bumps on an electrode of the nonvolatile programmable memory cell of FIG. 1 that can be implemented within embodiments of the present invention. The following U.S. patents, all of which are hereby expressly incorporated by reference into the present invention for purposes including, but not limited to describing the formation of a thin film magnetic recording medium (U.S. Pat. No. 5,053,250 issued to Baseman et al. on Oct. 1, 1991; U.S. Pat. No. 5,134,038 issued to Baseman et al. on Jul. 28, 1992; and U.S. Pat. No. 5,399,386 issued to Jahnes et al. on Mar. 21, 1995).

As shown in FIG. 4A, according to an exemplary embodiment, when fabricating the first electrode 110, a specified amount of a transient liquid metal 130 such as gallium (Ga) is deposited on a substrate 120. The present invention is not limited to the transient liquid metal 130 being of a particular type and may vary accordingly. According to an exemplary embodiment, the transient liquid metal 130 is one which does not wet the substrate 120 and is in liquid form when at room temperature. After depositing the liquid metal 130, a metal film interlayer, such as thin film of chromium (Cr), is deposited onto the liquid metal 130. The liquid metal 130 forms small beads 140 which react and freeze with the subsequently deposited thin Cr film. Then, as shown in FIG. 4B, according to an exemplary embodiment, a thin film 145 of ruthenium (Ru) is deposited on the combination of the liquid metal 130 and the Cr film, to form a bump 150.

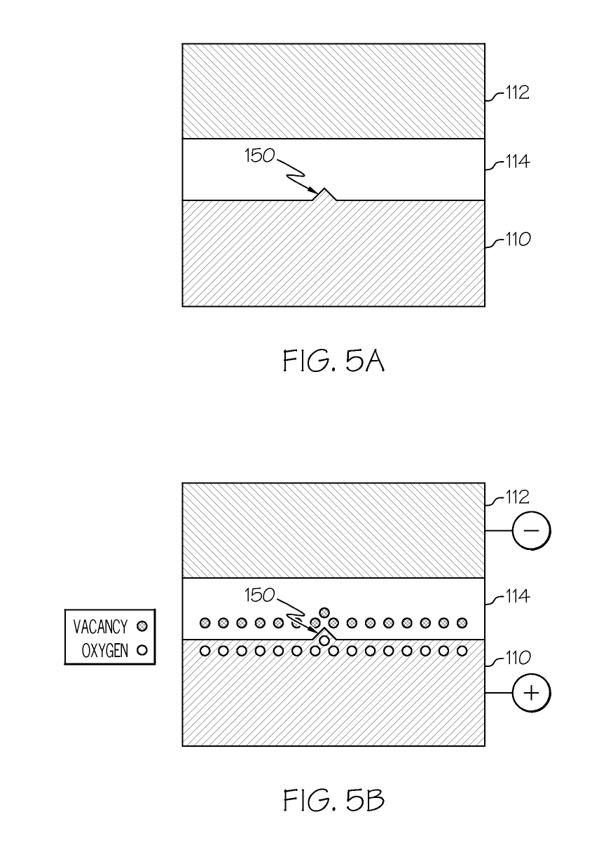

FIGS. 5A and 5B are schematic diagrams illustrating another example of a nonvolatile programmable memory cell with reference to FIG. 4B that can be implemented within embodiments of the present invention. Specifically, FIGS. 5A and 5B illustrate the formation of oxygen vacancies in a region immediately adjacent to the formed bump 150 shown in FIG. 4B.

As shown in FIG. 5A, the bump 150 is formed on the first electrode 110 near the electrode/oxide interface region of the first electrode 110 and the oxide layer 114. As shown in FIG. 5B, when an electrical signal is applied to the first electrode 110 oxygen ions from the oxide layer 114 migrate towards the first electrode 110. The oxygen ions from the oxide layer 114 become embedded in and oxidize the first electrode 110, thereby forming oxygen vacancies in the oxide layer 114 in a region immediately adjacent to the bump 150. The above-described process enables further localization of oxygen vacancies in the region immediately adjacent to the formed bump 150.

The flow diagram depicted herein is just an example. There may be many variations to this diagram or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method of incorporating oxygen vacancies near an electrode/oxide interface region of a complex metal oxide programmable memory cell, the method comprising:
forming a first electrode of a metallic material which remains metallic upon oxidation;
forming a second electrode facing the first electrode;
forming an oxide layer between the first and second electrodes;
applying an electrical signal to the first electrode such that oxygen ions from the oxide layer are embedded in and oxidize the first electrode; and
forming oxygen vacancies near the electrode/oxide interface region of the complex metal oxide programmable memory cell.

2. The method as in claim 1, wherein the metallic material of the first electrode comprises at least one of ruthenium, iridium or vanadium, and the oxide layer comprises a transition metal oxide.

3. The method as in claim 2, wherein when the memory cell is in a low resistance state, the oxide layer comprises oxygen vacancies and the first electrode is oxidized such that the first electrode and the oxide layer are in a low resistance-state, and when the memory cell is switched to a high resistance state, the density of oxygen vacancies near the electrode/oxide interface region is lowered and the first electrode is reduced such that the oxide layer is in a high resistance state while the first electrode remains in a low resistance state.

4. The method as in claim 1, wherein a thickness of the oxide layer forms a tunneling barrier such that the formation of oxygen vacancies at the electrode/oxide interface region generates a thinner tunneling barrier.

5. The method as in claim 1, wherein forming the first electrode comprises:
depositing a specified amount of a transient liquid metal film onto a substrate;
depositing another metal on a surface of the transient liquid metal film;
forming beads by reacting and freezing the transient liquid metal film with the subsequently deposited other metal;
depositing a metal film which remains metallic upon oxidation, and forming bumps on a surface of the first electrode; and
localizing oxygen vacancies in a region adjacent to the formed bumps on the first electrode.
